(19) United States
(12) Patent Application Publication
(10) Pub. No.: US 2017/0142863 A1
(43) Pub. Date: May 18, 2017

(54) INSERT MOLDED HEAT PIPE

(71) Applicants: Erin Hurbi, San Francisco, CA (US); Michael Nikkhoo, Saratoga, CA (US)

(72) Inventors: Erin Hurbi, San Francisco, CA (US); Michael Nikkhoo, Saratoga, CA (US)

(21) Appl. No.: 14/942,871

(22) Filed: Nov. 16, 2015

(51) Int. Cl. H05K 7/20; B23P 15/26; B29C 45/14

(52) U.S. Cl. CPC H05K 7/20336; B29C 45/14598; B23P 15/26; B23P 2700/09

(57) ABSTRACT

Examples are disclosed herein that relate to insert molding a heat pipe into a molded part. One example provides a method including inserting a heat pipe into a mold, injecting a material into the mold to at least partially surround the heat pipe and allowing the material to harden into a molded part that incorporates the heat pipe, and incorporating the molded part into a computing device.

### BACKGROUND

Computing devices may include electronic components, such as processors, that generate significant amounts of heat. As overheating may damage electronic components and potentially cause user discomfort, a computing device may utilize cooling devices, such as heat sinks and/or fans, to manage heat produced by the device.

### SUMMARY

Examples are disclosed herein that relate to insert molding a heat pipe into a molded part. One disclosed example provides a method including inserting a heat pipe into a mold, injecting a material into the mold to at least partially surround the heat pipe, allowing the material to harden into a molded part that incorporates the heat pipe, and incorporating the molded part into a computing device.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a block diagram schematically illustrating an example heat pipe in a device.

FIG. 2 is a flowchart illustrating an example method of incorporating a heat pipe into a molded part.

FIG. 3 shows an example device comprising a heat pipe incorporated into a molded component.

### DETAILED DESCRIPTION

As mentioned above, computing devices may utilize various devices to manage heat produced by components. For example, a computing device may use a heat pipe may be used to transfer and dissipate heat away from heat-producing components. Heat pipes are highly effective heat transfer components, but may be difficult to incorporate into devices in which space is limited, such as wearable devices. Further, heat pipes may be made from materials that are inflexible, thus complicating the incorporation of such heat pipes into flexible or movable device parts.

Accordingly, examples are disclosed herein that relate to encasing a heat pipe in a material via injection molding. Insert molding the heat pipe into an injection-molded part may help to efficiently accommodate a heat pipe into a part with limited internal volume and/or complex geometry. Further, selection of suitable materials for the molded part and/or the heat pipe may allow incorporation of the heat pipe into devices intended to flex or otherwise move.

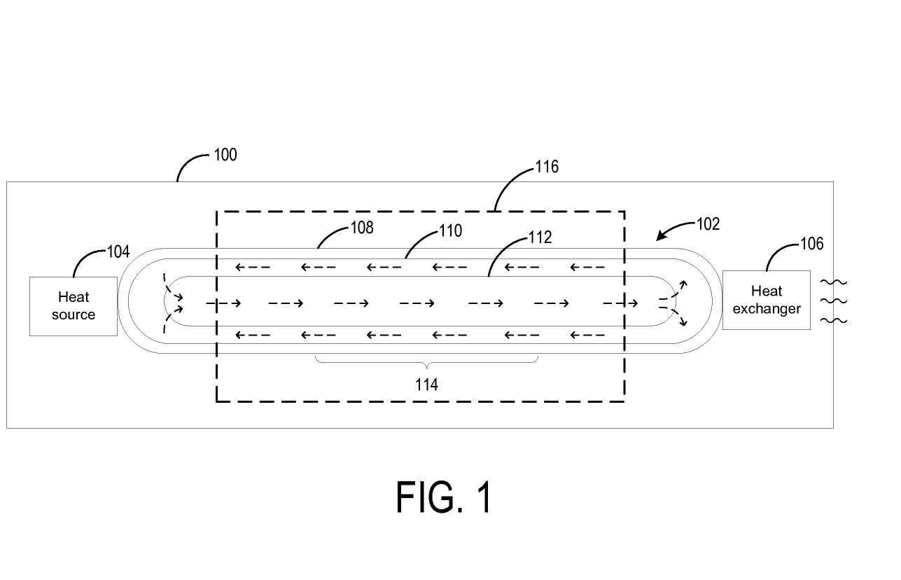

FIG. 1 schematically illustrates a device 100 incorporating an example heat pipe 102, and illustrates the transfer of heat from a heat source 104 to a heat exchanger 106. The heat pipe 102 includes a casing 108, a wick 110, and a cavity 112 in which a working fluid is located. The heat pipe 102 may function as a two-phase heat pipe. In such a configuration, the working fluid evaporates through absorption of thermal energy from the heat source 104. Upon evaporation, the working fluid migrates along the cavity 112 toward the heat exchanger 106, condenses back to a liquid phase, and flows back along the wick 110 toward the heat source 104, as illustrated by the arrows. The heat pipe 102 includes a middle portion 114 which may be referred to as the adiabatic section. It will be understood that the device 100 may include any other suitable type of heat pipe than that described.

As mentioned above, heat pipe 102 is insert molded into a part 116 that is incorporated into the device 100 after molding. The molding of the heat pipe 102 into the part 116 prior to assembly of the device 100 may facilitate use of a heat pipe in a device that has size constraints and/or a complex geometry.

The molded part 116 may be formed using any suitable molding process. For example, the molded part 116 may be produced via injection molding. In such a process, the heat pipe is placed into a mold at a desired location, and then a moldable material is injected into the mold, such that the moldable material hardens around the heat pipe 102 to form the molded part 116. In the depicted example, the molded part 116 encases a middle portion 114 of the heat pipe 102, while leaving the ends of the heat pipe 102 exposed. Molding over the adiabatic section of the heat pipe 102 may help to reduce heat loss throughout the middle portion 114 of the heat pipe 102. In the specific example of a wearable device, this may help to avoid outputting heat at regions of the device 100 that would be noticeable by a user. In other examples, any other suitable portion of, or an entirety of, a heat pipe may be molded into a molded part.

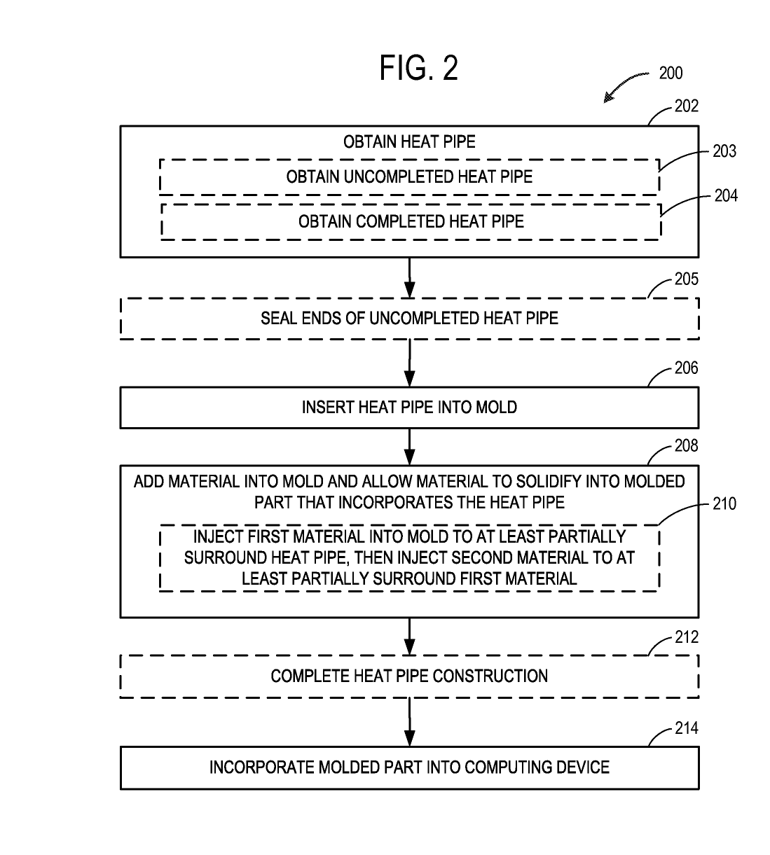

FIG. 2 shows an example method 200 of insert molding a heat pipe into a molded part. Method 200 includes, at 202, obtaining a heat pipe. Obtaining the heat pipe may include obtaining an uncompleted heat pipe at 203 (e.g. obtaining unassembled or partially assembled heat pipe components), or obtaining a completed heat pipe at 204. Where incorporated in an uncompleted completed state, the uncompleted heat pipe is completed after molding.

The heat pipe may be made using any suitable materials, including but not limited to copper, nickel, nickel-copper alloys, titanium, nickel-titanium alloys, stainless steel, aluminum, and other thermally conductive materials. The type of material used may be chosen based on a mold temperature being utilized, a desired thermal conductivity, and/or a type of plastic from which the molded part is made. To allow the heat pipe to be subsequently incorporated into a flexible device part, the heat pipe may include a flexible bellows section between the evaporator section and the condenser section. In other examples, the heat pipe may be formed at least partially from flexible materials, including but not limited to liquid silicon rubber, TPSiV thermoplastic elastomers, available from Dow Corning of Midland, Mich., polyurethanes, and other injection molded or laminated polymers. In other examples, any other suitable flexible or rigid material may be used, including but not limited to other commonly used plastics/resins than those mentioned above.

As mentioned above, in some examples a heat pipe may be incorporated into the molded part in an uncompleted state, for instance, in cases where a completed heat pipe may be prone to damage from thermal shock during injection molding. In some such examples, method 200 may include, at 205, sealing the ends of the uncompleted heat pipe prior to insert molding. Sealing the ends of the uncompleted heat pipe also may help to prevent contamination of the uncompleted heat pipe during molding. In other examples, such as when the uncompleted heat pipe may maintain its structure during molding without sealing the ends, the ends may remain unsealed. After molding, construction of the uncompleted heat pipe may be completed. In other examples, such as where thermal shock to the heat pipe during molding is not a significant risk, a completed heat pipe comprising a working fluid may be used for insert molding.

Method 200 further includes, at 206, inserting the heat pipe (completed or uncompleted) into a mold, and at 208, adding a moldable material into the mold and allowing the material to harden into a molded part that incorporates the heat pipe. Any suitable moldable material or materials may be used, including but not limited to poly(methyl methacrylate) (PMMA), polycarbonate, polyetherimide, polyethylene, and liquid silicon rubber. Likewise, any suitable molding process may be used, including but not limited to injection molding. In some examples, a double-shot injection molding process may be utilized, where two different molding materials are injected into the same mold. As such, method 200 may optionally include, at 210, injecting a first material into the mold to at least partially surround the heat pipe, and then injecting a second material to at least partially surround the first material. As a non-limiting example, the first, inner material may be polycarbonate, while the second, outer material may be liquid silicon rubber.

In some examples, the molded part may be formed such that the ends of the heat pipe remain exposed, e.g. outside of the molded part. In other examples, the heat pipe may be fully embedded into the molded part, and the ends of the heat pipe may be exposed once the molded part has been formed. In instances where an uncompleted heat pipe was molded into the part, method 200 may include, at 212, completing the construction of the heat pipe. This may include unsealing the uncompleted heat pipe if it was previously sealed, and also may include various processes related to adding a working fluid and sealing the heat pipe. Method 200 further includes, at 218, incorporating the molded part into a computing device.

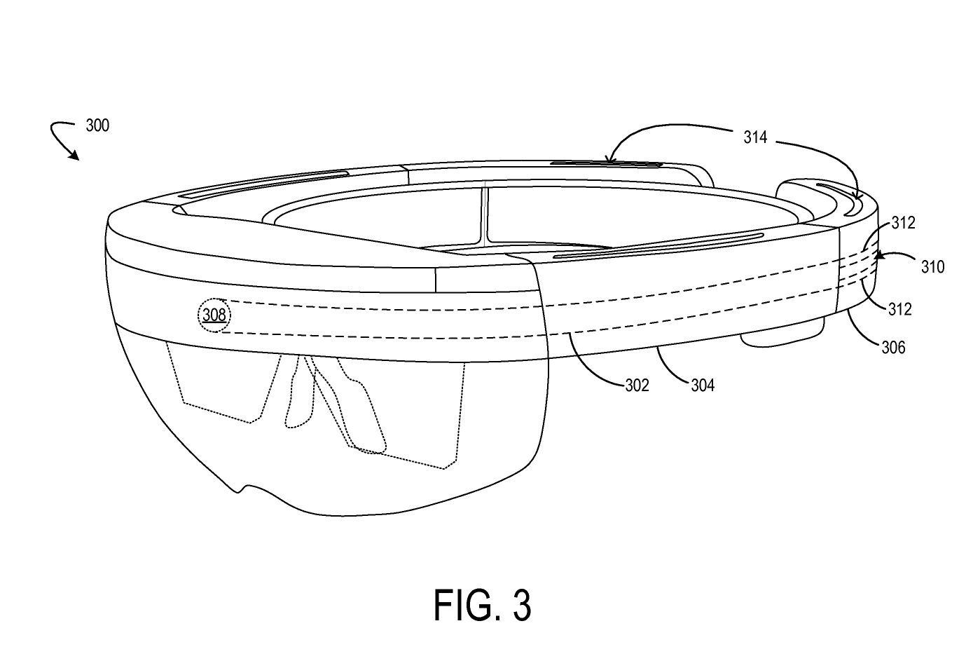

An insert molded heat pipe according to the present disclosure may be implemented in any suitable device. Examples include but are not limited to wearable computing devices such as head-mounted display devices, band devices, watches, etc. FIG. 3 illustrates an example of a wearable computing device in the form of an example head-mounted display device 300 including an insert molded heat pipe 302 as disclosed herein. The heat pipe 302 transfers heat from a heat source 308 located in a more forward region of the heat-mounted display device 300, to a heat dissipation region 310 located in a more rearward region of the head-mounted display device 300. As such, the heat pipe 302 may run along a band 304 of the device 300 configured to be worn around a person's head. This path may include a movable region, such as flexible or hinged portion 306 at which the band 304 may move to accommodate different head sizes. Thus, to accommodate such motion, the heat pipe 302 may be formed from a flexible material and/or include a flexible structure, such as a bellows. The heat source 308 may represent any suitable heat-producing component or system in the device. The depicted heat dissipation region 310 includes heat exchangers 312 to facilitate heat dissipation into the surrounding environment of the head-mounted display device 300 through vents 314, but may have any other suitable structure.

Any suitable type of heat pipe may be used in the head-mounted display device 300. For example, the heat pipe 302 may take the form of a two-phase heat pipe that cycles a working fluid from liquid to vapor to transfer heat from the heat source 308 toward the heat dissipation region 310. As another example, the heat pipe 302 may take the form of a single-phase heat pipe conduit loop. It will be understood that the heat pipe 302 may have any suitable size and shape. It further will be understood that a device may include more than one insert molded heat pipe.

Another example provides a method comprising inserting a heat pipe into a mold, injecting a material into the mold to surround the heat pipe and allowing the material to harden into a molded part that incorporates the heat pipe, and incorporating the molded part into a computing device. The method may additionally or alternatively include sealing ends of the heat pipe prior to inserting the heat pipe into the mold. In this example, the ends of the heat pipe may be additionally or alternatively located outside of the molded part. The method may additionally or alternatively include after allowing the material to harden into the molded part, opening the ends, filling the heat pipe with a working fluid, and resealing the ends of the heat pipe. Incorporating the molded part into the computing device may additionally or alternatively include incorporating the molded part into a wearable computing device. The wearable computing device may additionally or alternatively include a head-mounted display device. The molded part may additionally or alternatively be incorporated into the head-mounted display device in a position that extends at least partially from a heat-producing component located adjacent a front of the head-mounted display device toward a heat dissipation region located toward a rear of the head-mounted display device. Injecting the material into the mold may additionally or alternatively include injecting a first material into the mold to coat the heat pipe, and then injecting a second material different from the first material to surround the first material. The first material may additionally or alternatively include polycarbonate, and the second material may additionally or alternatively include liquid silicon rubber.

Another example provides a computing device, comprising a heat-producing component, a heat dissipation region, and a molded part comprising a heat pipe, the molded part extending at least partially from the heat-producing component to the heat dissipation region. The computing device may additionally or alternatively include a wearable device. The computing device may additionally or alternatively include a head-mounted display device. The heat-producing component may additionally or alternatively be located adjacent a front of the head-mounted display device, and wherein the heat dissipation region is located toward a rear of the head-mounted display device. The molded part may additionally or alternatively include a flexible portion. The molded part may additionally or alternatively include a polycarbonate material surrounding the heat pipe, and a liquid silicon rubber material surrounding the polycarbonate material. The heat pipe may additionally or alternatively include a metal material.

Another example provides a method comprising forming a heat pipe, sealing ends of the a heat pipe, inserting the heat pipe into a mold, injecting a material into the mold and allowing the material to harden into a molded part that incorporates the heat pipe while leaving the ends of the heat pipe exposed, opening the sealed ends of the heat pipe, filling the heat pipe with a working fluid, resealing the ends of the pipe to form a heat pipe, and incorporating the molded part into a computing device. Incorporating the molded part into the computing device may additionally or alternatively include incorporating the molded part into a wearable computing device. The wearable computing device may additionally or alternatively include a head-mounted display device. The molded part may additionally or alternatively be incorporated into the head-mounted display device in a position that extends at least partially from a heat-producing component located adjacent a front of the head-mounted display device toward a heat dissipation region located toward a rear of the head-mounted display device.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A method comprising:
inserting a heat pipe into a mold;
injecting a material into the mold to at least partially surround the heat pipe and allowing the material to harden into a molded part that incorporates the heat pipe; and
incorporating the molded part into a computing device.

2. The method of claim 1, wherein the heat pipe is an uncompleted heat pipe, and further comprising sealing ends of the heat pipe prior to inserting the heat pipe into the mold.

3. The method of claim 2, wherein the ends of the heat pipe are located outside of the molded part.

4. The method of claim 2, further comprising, after allowing the material to harden into the molded part, opening the ends, filling the heat pipe with a working fluid, and resealing the ends of the heat pipe.

5. The method of claim 1, wherein incorporating the molded part into the computing device comprises incorporating the molded part into a wearable computing device.

6. The method of claim 5, wherein the wearable computing device comprises a head-mounted display device.

7. The method of claim 6, wherein the molded part is incorporated into the head-mounted display device in a position that extends at least partially from a heat-producing component located adjacent a front of the head-mounted display device toward a heat dissipation region located toward a rear of the head-mounted display device.

8. The method of claim 1, wherein injecting the material into the mold comprises injecting a first material into the mold to coat the heat pipe, and then injecting a second material different from the first material to surround the first material.

9. The method of claim 8, wherein the first material comprises polycarbonate, and wherein the second material comprises liquid silicon rubber.

10. A computing device, comprising:
a heat-producing component;
a heat dissipation region; and
a molded part comprising a heat pipe, the molded part extending at least partially from the heat-producing component to the heat dissipation region.

11. The computing device of claim 10, wherein the computing device comprises a wearable device.

12. The computing device of claim 11, wherein the computing device comprises a head-mounted display device.

13. The computing device of claim 12, wherein the heat-producing component is located adjacent a front of the head-mounted display device, and wherein the heat dissipation region is located toward a rear of the head-mounted display device.

14. The computing device of claim 10, wherein the molded part comprises a flexible portion.

15. The computing device of claim 10, wherein the molded part comprises a polycarbonate material surrounding the heat pipe, and a liquid silicon rubber material surrounding the polycarbonate material.

16. The computing device of claim 10, wherein the heat pipe comprises a metal material.

17. A method comprising:
forming a heat pipe;
sealing ends of the heat pipe;
inserting the heat pipe into a mold;
injecting a material into the mold and allowing the material to harden into a molded part that incorporates the heat pipe while leaving the ends of the heat pipe exposed;
opening the sealed ends of the heat pipe;
filling the heat pipe with a working fluid;
resealing the ends of the heat pipe; and
incorporating the molded part into a computing device.

18. The method of claim 17, wherein incorporating the molded part into the computing device comprises incorporating the molded part into a wearable computing device.

19. The method of claim 18, wherein the wearable computing device comprises a head-mounted display device.

20. The method of claim 19, wherein the molded part is incorporated into the head-mounted display device in a position that extends at least partially from a heat-producing component located adjacent a front of the head-mounted display device toward a heat dissipation region located toward a rear of the head-mounted display device.
